(19) United States
(12) Patent Application Publication
(10) Pub. No.: US 2024/0282591 A1
(43) Pub. Date: Aug. 22, 2024

(54) TOOLS AND METHODS FOR SURFACE LEVELING

(71) Applicant: Intel Corporation, Santa Clara, CA (US)

(72) Inventors: Oladeji FADAYOMI, Maricopa, AZ (US); Shaojiang CHEN, Chandler, AZ (US); Jeremy ECTON, Gilbert, AZ (US); Matthew TINGEY, Mesa, AZ (US); Srinivas PIETAMBARAM, Chandler, AZ (US); Leonel ARANA, Phoenix, AZ (US)

(21) Appl. No.: 18/171,683

(22) Filed: Feb. 21, 2023

(51) Int. Cl. H01L 21/48; C23F 1/02

(52) U.S. Cl. CPC H01L 21/486; C23F 1/02

(57) ABSTRACT

The present disclosure is directed to a planarization tool having at least one module with a target holder for supporting a target with a metal layer, at least one of a plurality of etch inhibitor dispensers for discharging an etch inhibitor toward the target, and a plurality of nozzles for discharging a chemical etchant at an angle towards the target to perform selective removal of the metal layer for planarization of the target. In an aspect, the plurality of etch inhibitor dispensers and the plurality of nozzles may be combined as a single unit to discharge the chemical etchant and the etch inhibitor together. In another aspect, the plurality of etch inhibitor dispensers and the plurality of nozzles may be configured in a single module or separate modules.

### BACKGROUND

For integrated circuit design and fabrication, the need to improve performance and lower costs are constant challenges. As transistors continue to shrink in size, it is becoming more and more difficult and costly to realize high-volume manufacturing for semiconductors. Cost savings may be potentially realized by building dies on semiconductor panels rather than semiconductor wafers. By using a rectangular panel as a carrier or substrate, panel-level fan-out technology, which uses a molded embedded design, offers the potential for lower production cost due to a higher area utilization ratio of the carrier and better economical manufacturing, especially for large heterogeneous packages.

However, it is becoming more evident that manufacturing these types of packages may require a rigid core, such as a thin glass core as part of the substrate package. A glass core compared to a conventional epoxy core offers several advantages including a higher plated through hole density, lower signal losses, lower total thickness variation, etc. However, enabling a high aspect ratio thru glass via (TGV) in a glass core may present challenges. For example, to adequately fill the TGV, a significant amount of copper may need to be plated onto the surface of the glass core (as high as 20-50 μm). In addition, after filling the TGVs using a plating process, the formation of significant copper recesses (e.g., approximately 10-15 μm deep) may be observed around the TGVs.

To remove the copper recesses and planarize the surface copper layer, the use of conventional copper etching approaches, which are isotropic, may result in significant etching into the TGVs. A recess formed in the TGV after a copper bulk etching process may cause a reliability risk as the TGV below a recessed pad may be prone to cracking. It is therefore important to have anisotropic copper etching solutions that can effectively flatten the recesses and remove copper on the surface while avoiding significant over-etching or forming recesses in the TGVs and the relatively high cost of chemical mechanical polishing.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows an exemplary representation of a semiconductor planarization tool according to an aspect of the present disclosure;

FIG. 2 shows an exemplary representation of a section of a glass core with through glass vias before planarization according to an aspect of the present disclosure;

FIG. 3 shows an exemplary representation of a section of a glass core in a module of the present planarization tool according to an aspect of the present disclosure;

FIG. 3A shows an exemplary representation of a section of a glass core with an etch inhibitor positioned in recess areas after an operation in a module according to an aspect of the present disclosure;

FIG. 4 shows an exemplary representation of a section of a glass core with positioned etch inhibitor in a module of the present planarization tool according to an aspect of the present disclosure;

FIG. 4A shows an exemplary representation of a section of a glass core with partially planarized metal layers after an operation in a module according to an aspect of the present disclosure;

FIG. 5 shows an exemplary representation of a cleaned, partially planarized section of a glass core in a module of the present planarization tool according to an aspect of the present disclosure;

FIG. 5A shows an exemplary representation of a partially planarized section of a glass core with positioned etch inhibitor after an operation in a module according to an aspect of the present disclosure;

FIG. 6 shows an exemplary representation of a partially planarized section of a glass core with positioned etch inhibitor in a module of the present planarization tool according to an aspect of the present disclosure;

FIG. 7 shows a simplified flow diagram for an exemplary method according to an aspect of the present disclosure; and

FIG. 8 shows a simplified flow diagram for another exemplary method according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

The present disclosure provides solutions that enable anisotropic etching to effectively flatten/planarize a copper surface and prevents over-etching; in particular, the end portions of through glass vias may be protected from excessive over-etching. The disclosed planarization tool may be configured with several modules to provide an etch inhibitor at selected locations of a target surface to shield those locations and inhibit the removal of the copper by a chemical etchant. The modules may include a plurality of angled nozzles and dispensers to position/discharge the etch inhibitor and etching chemistry, either singly or simultaneously. The operations for flattening/planarizing the copper surface may be performed one side or two sides at a time by using an appropriately configured planarization tool.

In another aspect, the present disclosure is directed to a planarization tool having at least one module with a target holder and at least one of a plurality of etch inhibitor dispensers for discharging an etch inhibitor toward a target with a metal layer that is supported on the target holder, and/or a plurality of nozzles for discharging a chemical etchant at an acute angle towards the target to perform selective removal of the metal layer for planarization of the target. In an aspect, the plurality of etch inhibitor dispensers and the plurality of nozzles may be combined as a single unit in a module to discharge the chemical etchant and the etch inhibitor together. In another aspect, the plurality of etch inhibitor dispensers and the plurality of nozzles may be configured in a single module or separate modules. In another aspect, the present planarization tool may have modules (e.g., rinsing and drying modules) for cleaning the target (i.e., removing the etch inhibitor and the chemical etchant). In a further aspect, the present planarization tool may have a filtering system to remove the etch inhibitor from the cleaning effluent discharged from a cleaning module.

In an aspect, the present disclosure is directed to a method that includes providing a target with first and second surfaces and openings extending from the first surface to the second surface for through-hole vias, depositing metal on the first surface and the second surface of the target, and filling the openings to form the through-hole vias. In an aspect, the deposited metal forms a first metal layer with first recess areas that are aligned with each through-hole via on the first surface, and a second metal layer is formed with second recess areas that are aligned with each through-hole via on the second surface. The method further provides for dispensing an etch inhibitor over a first section of each first recess area in the first metal layer and discharging a chemical etchant onto the first metal layer to at least partially remove the first metal layer from selected areas that are unobstructed by the etch inhibitor, and dispensing the etch inhibitor over a first section of each second recess area in the second metal layer and discharging the chemical etchant onto the second metal layer to at least partially remove the second metal layer from selected areas that are unobstructed by the etch inhibitor.

In yet another aspect, the present disclosure is directed to a method that includes providing a planarization tool having at least one module, a target holder supporting a target, a plurality of nozzles, and a plurality of etch inhibitor dispensers. In an aspect, the target has top and bottom surfaces and a plurality of openings extending from the top surface to the bottom surface for a plurality of through-hole vias, and the top surface is covered by a top metal layer with a top recess area formed in the top metal layer and the bottom surface is covered by a bottom metal layer with a bottom recess area formed in the bottom metal layer at each through-hole via. In an aspect, the operations of the planarization tool enable the planarizing of the target by the steps of providing an etch inhibitor positioned over a first section of each of the top and bottom recess areas, respectively, in the top and bottom metal layers on the target, and discharging a chemical etchant at a first angle towards the target to selectively remove the top and bottom metal layers from areas that are unobstructed by the etch inhibitor, and cleaning the target to remove the etch inhibitor and the chemical etchant.

The technical advantages of the present disclosure include, but are not limited to:
(i) Providing a planarizing anisotropic etching tool and process that avoids excessive over-etching, especially at the end portions of through glass vias that are proximal to the glass core surfaces;
(ii) Enabling the use of high aspect ratio thru glass vias (TGV) in glass cores for package substrates; and
(iii) Providing a planarization process that either eliminates or greatly reduces the need for chemical mechanical polishing.

To more readily understand and put into practical effect the present planarization tool and methods for its use, which may be used for planarizing a glass core to be incorporated in a package substrate, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

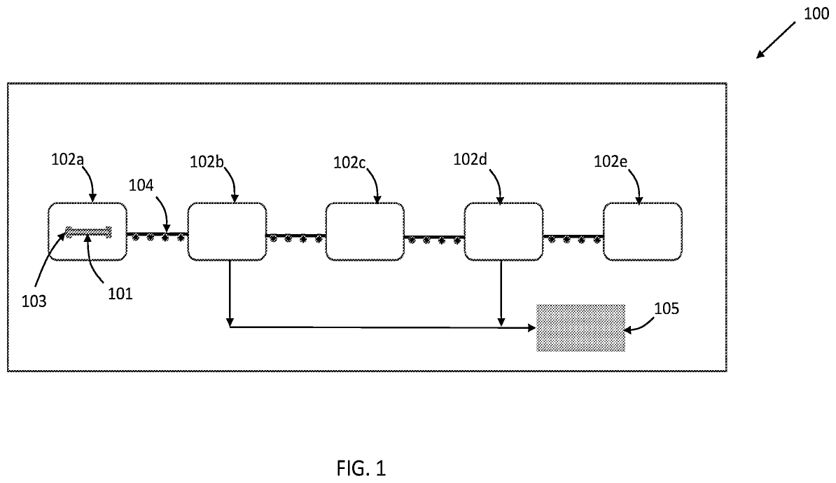

FIG. 1 shows an exemplary representation of a semiconductor planarization tool 100 according to an aspect of the present disclosure. The planarization tool 100 may be used to level the surfaces of a target 100 by operations that may be performed in several modules, which are shown as modules 102a, 102b, 102c, 102d, and 102e. In an aspect, the target 100, which may be a glass core for a semiconductor package substrate, may be positioned in a target holder 103 or support for processing, as shown in module 102a, and will be a feature of every module. In an aspect, the target holder 103 may be a conventional holder, such as a frame, a stage, a chuck, or a support carrier (all not shown) that securely holds the target 100 in place for processing and may be sized for a panel, wafer, or other shapes, and may also facilitate the target being rotated or inverted as needed within a module. In another aspect, the target 100 may be transported between modules 102a, 102b, 102c, 102d, and 102e by a handling system 104, which may include standard roller/conveyance mechanisms having a frame with clamps, robotic arms, and other conventional devices for moving panels and/or wafers.

In yet another aspect, the modules 102a, 102b, 102c, 102d, and 102e may be configured to perform specific operations, including dispensing the etch inhibitor, removing/positioning the etch inhibitor, discharging chemical etchant, and cleaning the targets, as discussed below. For example, the module 102a may be an etch inhibitor dispensing module, the module 102b may be a blower module for positioning and removing excess the etch inhibitor, the module 102c may be a chemical etchant dispensing module, the module 102d may be a rinsing module, and the module 102e may be a drying module. In another aspect, the number of modules may be determined based on the processing and handling requirements for a target; for example, a planarization tool may have a range of between 5 to 10 modules. In yet another aspect, a module may be configured to provide one-sided operations, which requires a target to be inverted for its bottom side to be processed, or two-sided operations, which allows a target to have both sides processed simultaneously.

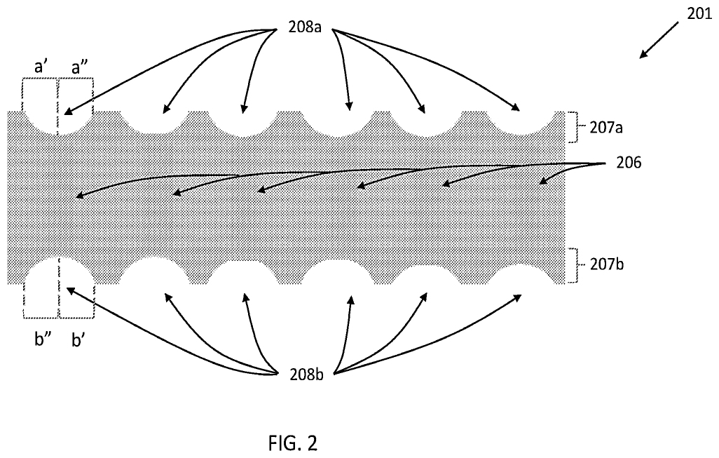

FIG. 2 shows an exemplary representation of a section of a glass core or target 201 with a plurality of through glass vias (TGVs), which are shown as 206, before planarization/flattening according to an aspect of the present disclosure. The glass core 201 may have a first or top metal layer 207a and a second or bottom metal layer that are formed when the TGVs 206 are formed. In an aspect, the first and second metal layers 207a and 207b may be formed by a metal deposition process that is performed either simultaneously, or consecutively (i.e., a first surface followed by a second surface), on the top and bottom surfaces of the glass core 201 and may have a thickness of up to 50 μm. The TGVs 206 and the first and second metal layers 207a and 207b may be formed of copper or other conductive metal, such as aluminum.

In another aspect, during the metal deposition process, the first metal layer 207a may have a plurality of first or top recess areas 208a that form near or at each end portion of the TGVs 206, and the second metal layer 207b may have a plurality of second or bottom recess areas 208b that form at or near each other end portion of the TGVs 206, as shown in FIG. 2. The recess areas may be formed as “structural byproducts” of the formation of the TGVs. In an aspect, the first recess areas 208a may have a first section a′ and a second section a″, which may be alternatively provided with an etch inhibitor, and the second recess areas 208b may have a first section b′ and a second section b″, which may also be alternatively provided with an etch inhibitor, according to the present disclosure.

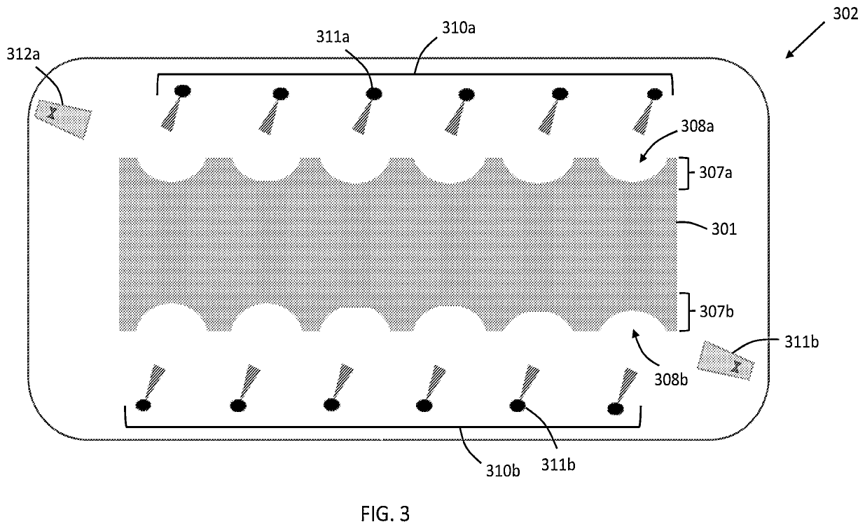

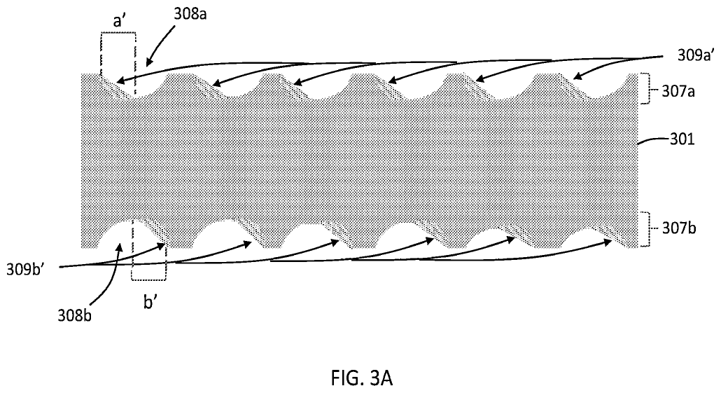

FIG. 3 shows an exemplary representation of a section of a glass core or target 301 in a module 302 of a planarization tool (not shown) according to an aspect of the present disclosure. The module 302 may be used to provide the glass core 301 with an etch inhibitor using a first plurality of etch inhibitor dispensers 310a, which may be located at an upper portion of module 302. In the aspect shown in FIG. 3, the module 302 may have a second plurality of etch inhibitor dispensers 310b, which may be located at a lower portion of the module 302, to enable two-sided processing of the glass core 301. In an aspect, the etch inhibitor dispensers 310a and 310b may be “guns” or nozzles that are components of a conventional pressurized particle delivery system that includes a holding tank containing the insoluble etch inhibitor, a pump/blower, and an inlet manifold attached to the plurality of etch inhibitor dispensers 310a and 310b.

In another aspect, the number of etch inhibitor dispensers may be determined based on the dimensions and processing requirements for a glass core; for example, a module for dispensing the etch inhibitor may have up to 100 dispensers positioned in the upper portion of the module, and for two-sided processing, may have up to another 100 dispensers in the lower portion of the module. In yet another aspect, each of the first and second plurality of etch inhibitor dispensers 310a and 310b, respectively, may have rotation mechanisms 311a and 311b to direct the positioning of the etch inhibitor. The rotation mechanisms 311a and 311b may be connected to a controller (not shown).

In this aspect, the first plurality of etch inhibitor dispensers 310a may position the etch inhibitor into a plurality of first recess areas 308a in a first metal layer 307a and the second plurality of etch inhibitor dispensers 310b may position the etch inhibitor into a plurality of second recess areas 308b in a second metal layer 307b. The placement of an etch inhibitor may shield or inhibit the removal of the underlying section of a metal layer.

In another aspect, an etch inhibitor may be combined with a chemical etchant and discharged together by a plurality of single discharge units (not shown) in a module configured with dispensers that can handle both the etch inhibitor and the chemical etchant. For two-sided processing, there may be a top plurality of single discharge units and a bottom plurality of single discharge units. In yet another aspect, a module may be configured to have a plurality of etch inhibitor dispensers and a plurality of nozzles for discharging chemical etchant that are positioned proximal to each other, e.g., side-by-side. For two-sided processing, there may be a top set of side-by-side dispensers and nozzles and a bottom set of side-by-side dispensers and nozzles (not shown).

As shown in FIG. 3, the module 302 may have one or more blowers 312a positioned in the upper portion of module 302 to assist in the positioning of the etch inhibitor and remove excess etch inhibitor from the plurality of first recess areas 308a. Similarly, for two-sided processing of the glass core 301, the module 302 may have one or more blowers 312b positioned in the lower portion of module 302 to assist in the positioning of the etch inhibitor and remove excess etch inhibitor from the plurality of recess areas 308b. In another aspect, the blowers 312a and 312b may be placed in a separate module that is specifically designated for the positioning of the etch inhibitor and removing excess etch inhibitor from the plurality of first and second recess areas 308a and 308b. The dimensions of the plurality of first recess areas 308a and second recess areas 308b (i.e., width and depth) will determine how much etch inhibitor may need to be applied onto the glass core 301.

FIG. 3A shows an exemplary representation of the section of the glass core 301 with an etch inhibitor positioned in the plurality of first and second recess areas 308a and 308b after an operation in an etch inhibitor dispensing module, such as shown in FIG. 3, according to an aspect of the present disclosure. In this aspect, the plurality of first recess areas 308a in the first metal layer 307a may have each of their first section a′ filled with an etch inhibitor 309a′, and the plurality of second recess areas 308b in the second metal layer 307b may have each of their first section b′ filled with an etch inhibitor 309b′. The etch inhibitor 309a′ and 309b′ may shield or obstruct the anisotropic etching of the first sections a′ and b′, respectively, of the plurality of first and second recess areas 308a and 308b. In an aspect, the etch inhibitors 309a′ and 309b′ may be made of solid metal or organic material particles, including, for example, titanium, nickel, gold, polymers, and other chemical etchant-resistant materials. In addition, the etch inhibitors may have a range of sizes, including, for example, metal nanoparticles, metal “slugs” having a size range of 1 μm to 100 μm, and organic polymer particles having a size of less than approximately 100 μm.

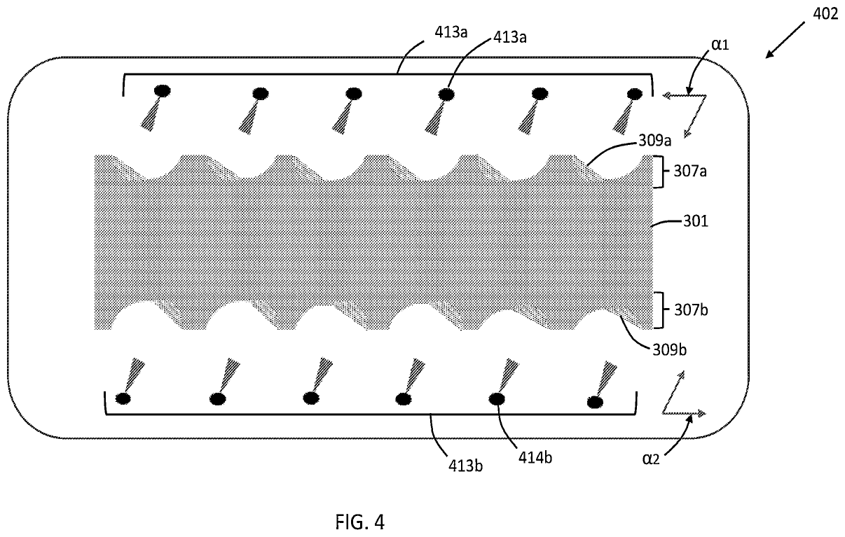

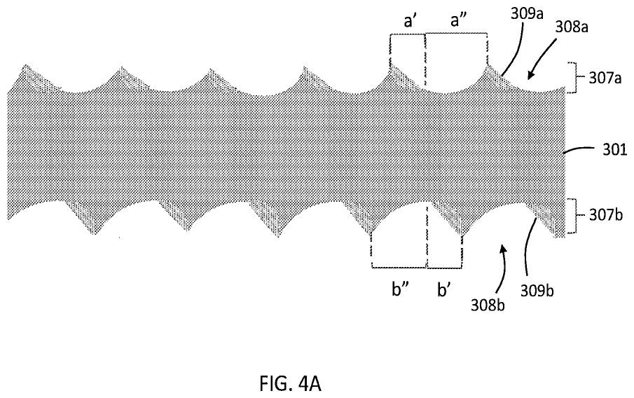

FIG. 4 shows an exemplary representation of a section of the glass core 301 with positioned etch inhibitors 309a′ and 309b′ in a chemical etching module 402 of the present planarization tool according to an aspect of the present disclosure. In this aspect, the module 402 may have a first or top plurality of nozzles 413a that may be positioned at an upper portion of the module 402 and may have a second or bottom plurality of nozzles 413a that may be positioned at a lower portion of the module 402 to enable two-sided processing of the glass core 301. In an aspect, the plurality of nozzles 413a and 413b may be spray nozzles that are components of a conventional pressurized fluid delivery system that includes a holding tank containing the chemical etchant, a pump, and an inlet manifold attached to the plurality of nozzles 413a and 413b.

In another aspect, the number of nozzles may be determined based on the dimensions and processing requirements for a glass core; for example, a module for dispensing the chemical etchant may have up to 100 dispensers positioned in the upper portion of the module 402, and for two-sided processing, may have up to another 100 dispensers in the lower portion of the module. In yet another aspect, each of the first and second plurality of nozzles 413a and 413b, respectively, may have rotation mechanisms 414a and 414b to direct the discharge of the chemical etchant. The rotation mechanisms 414a and 414b may be connected to a controller (not shown).

In an aspect, the first plurality of nozzles 413a may be used to discharge a chemical etchant at an angle α₁ towards the first metal layer 307a, which is partially shielded by the etch inhibitor 309a′, and the second plurality of nozzles 413b may be used to discharge a chemical etchant at an angle α₂ towards the second metal layer 307b, which is partially shielded by the etch inhibitor 309b′. The angle α1 and angle α ₂ may be adjustable, e.g., set to be identical or different depending on the positioning of the etch inhibitors 309a′ and 309b′ and/or the dimensions of the glass core 301, including the dimensions of the plurality of first recess areas 308a and second recess areas 308b (i.e., width and depth). The angle α1 and angle α ₂ may be acute angles (i.e., between 90° and 0°). In a further aspect, for metal layers made of copper, a conventional chemical etch, such as ferric chloride, cupric chloride, hydrogen peroxide, alkaline etchants, and others may be used in the present disclosure.

FIG. 4A shows an exemplary representation of the section of the glass core 301 with partially planarized metal layers 307a and 307b after an operation in a chemical etchant dispensing module, such as shown in FIG. 4, according to an aspect of the present disclosure. In this aspect, the plurality of first recess areas 308a may have their first section a′ with the etch inhibitor 309a′ shielded from the anisotropic etching, while a portion of the first metal layer 307a may be selectively removed from the second section a″, and similarly, the plurality of second recess areas 308b may have their first section b′ with the etch inhibitor 309b′ shielded from the anisotropic etching, while a portion of the second metal layer 307b may be selectively removed from the second section b″.

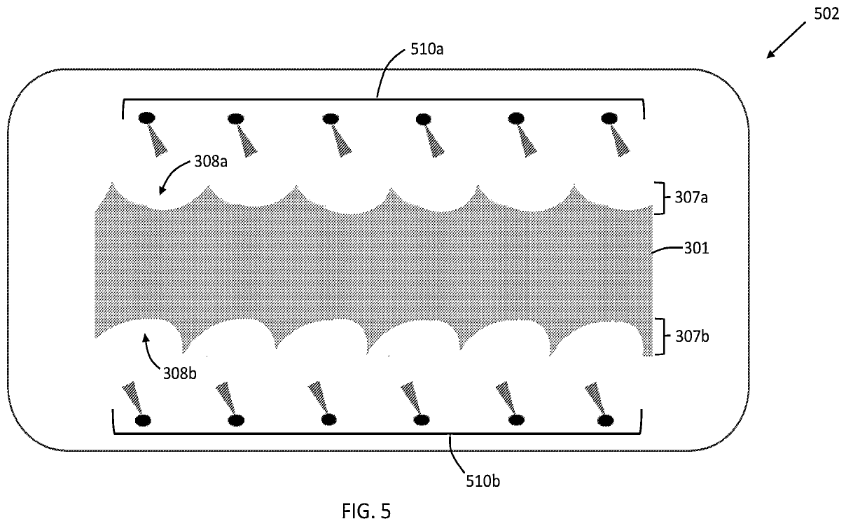

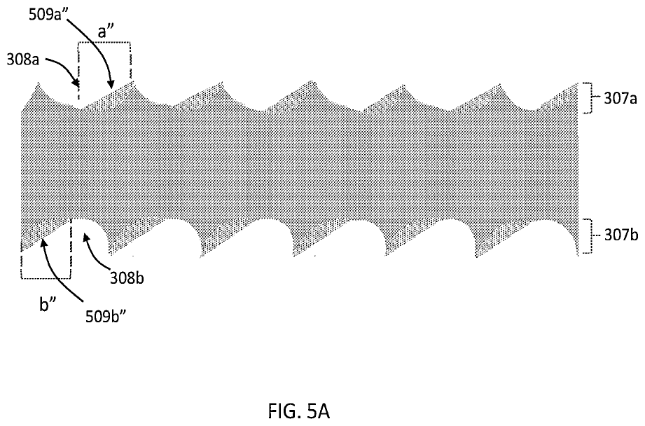

FIG. 5 shows an exemplary representation of a cleaned, partially planarized glass core 301 in a module 502 of the present planarization tool according to an aspect of the present disclosure. The partially planarized glass core 301 may be cleaned, e.g., rinsed to remove the etch inhibitor and chemical etchant and followed by drying in one or more cleaning modules, which may be two of the modules shown in FIG. 1 above. The module 502 may be used to provide the glass core 301 with an “additional” etch inhibitor, i.e., a second application of the etch inhibitor, using a first plurality of etch inhibitor dispensers 510a, which may be located at an upper portion of module 502. In the aspect shown in FIG. 5, the module 502 may have a second plurality of etch inhibitor dispensers 510b, which may be located at a lower portion of the module 502, to enable two-sided processing of the glass core 301. It should be understood that the modules shown in FIG. 3 and FIG. 5 may have similar or identical features for dispensing an etch inhibitor.

In another aspect, the number of etch inhibitor dispensers may be determined based on the dimensions and processing requirements for a glass core; for example, a module for dispensing the etch inhibitor may have up to 100 dispensers positioned in the upper portion of the module, and for two-sided processing, may have up to another 100 dispensers in the lower portion of the module.

In a further aspect, a planarization tool may have a single module for dispensing the etch inhibitor (i.e., first application, second application, etc.), and a first and second plurality of etch inhibitor dispensers in the single module may be rotatable and aligned to provide the appropriate positioning of the etch inhibitor for each application or particular operating step in the planarization process.

FIG. 5A shows an exemplary representation of a partially planarized glass core 301 with an additional/second application of etch inhibitor positioned in the first and second recess areas 308a and 308b after an operation in an etch inhibitor dispensing module, such as shown in FIG. 5, according to an aspect of the present disclosure. In this aspect, the plurality of first recess areas 308a may have each of their second section a″ filled with an additional etch inhibitor 509a″ and the second recess areas 308b have each of their second section b″ filled with an additional etch inhibitor 509b″. The additional etch inhibitor 509a″ and 509b″ may shield or obstruct the anisotropic etching of the second sections a″ and b″, respectively, of the first recess areas 308a in the first metal layer 307a and the second recess areas 308a in the second metal layer 307b. In an aspect, the etch inhibitors 509a′ and 509b′ may be made of solid metal or organic material particles, including, for example, titanium, nickel, gold, polymers, and other chemical etchant-resistant materials. In addition, the etch inhibitors may have a range of sizes, including, for example, metal nanoparticles, metal “slugs” having a size range of 1 μm to 100 μm, and organic polymer particles having a size of less than approximately 100 μm.

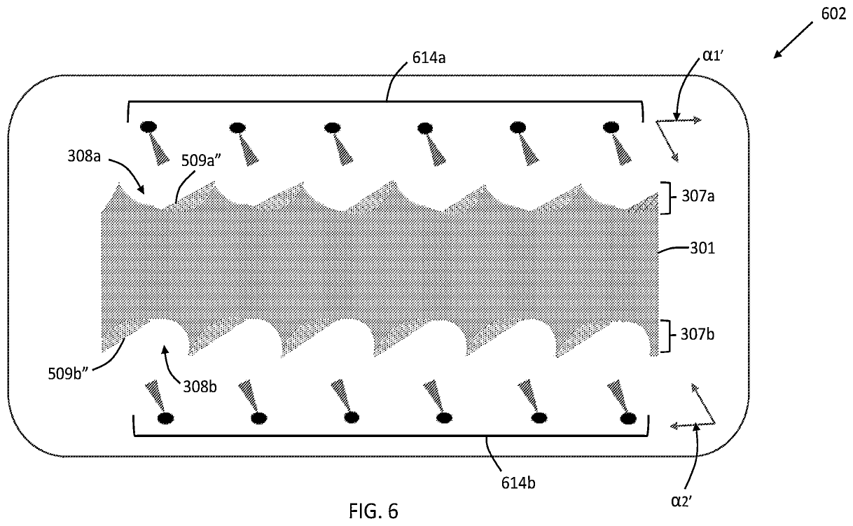

FIG. 6 shows an exemplary representation of a section of the partially planarized glass core with positioned additional etch inhibitor 509a″ and 509b″ in a chemical etching module 602 of the present planarization tool, according to an aspect of the present disclosure. In this aspect, the module 602 may have a first or top plurality of nozzles 614a that may be positioned at an upper portion of the module 602 and may have a second or bottom plurality of nozzles 614a that may be positioned at a lower portion of the module 602 to enable two-sided processing of the glass core 301. Accordingly, it should be understood that the modules shown in FIG. 4 and FIG. 6 may have similar or identical features for discharging the chemical etchant.

In another aspect, the number of nozzles may be determined based on the dimensions and processing requirements for a glass core; for example, a module for dispensing the chemical etchant may have up to 100 dispensers positioned in the upper portion of the module, and for two-sided processing, may have up to another 100 dispensers in the lower portion of the module.

In an aspect, the first plurality of nozzles 614a may be used to discharge an additional or second application of chemical etchant at an angle α₁ ″ towards the first metal layer 307a, which is partially shielded by the etch inhibitor 509a″, and the second plurality of nozzles 614b may be used to discharge an additional chemical etchant at an angle α₂′ towards the second metal layer 307b, which is partially shielded by the etch inhibitor 509b″. The angle α₁′ and angle α₂′ may be acute angles (i.e., between 90° and 0°). The angle α₁′ and angle α₂′ may be adjustable, e.g., set to be identical or different depending on the positioning of the etch inhibitors 509a″ and 509b″ and/or the dimensions of the glass core 301.

In a further aspect, a planarization tool may have a single module for dispensing a chemical etchant (i.e., first application, second application, etc.), and a first and second plurality of etch inhibitor dispensers in the single module may be rotatable and aligned to provide the appropriate direction and/or angle of discharge for each application or particular operating step in the planarization process.

According to the present disclosure, the planarization process for a glass core with through glass vias using the present planarization tool may need only “a single pass” for two-sided processing-a first application of an etch inhibitor followed by a first application of a chemical etchant, a cleaning step, a second application of the etch inhibitor followed by a second application of the chemical etchant, and a final cleaning step. If needed, a second pass (i.e., a repeat of the first and second application) may be performed until the glass core is level. It should be understood that all placements of the etch inhibitor will protect the end portions of the through glass vias from any significant removal of metal that is below the top and bottom surface levels of the glass core.

In a further aspect, the planarization process may include an optical inspection of the glass core using standard techniques to ensure the complete removal of the metal layers from the top and bottom surfaces of a glass core. In the event of the presence of any residual metal on the top or bottom surfaces being uncovered, a short chemical mechanical polishing may be performed to remove any residual metal on a surface of the glass core.

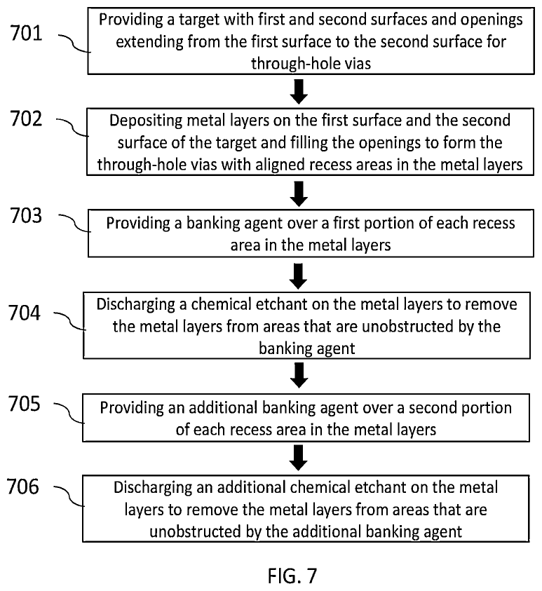

FIG. 7 shows a simplified flow diagram for an exemplary method according to an aspect of the present disclosure.

The operation 701 may be directed to providing a target with first and second surfaces and openings extending from the first surface to the second surface for through-hole vias.

The operation 702 may be directed to depositing metal layers on the first surface and the second surface of the target and filling the openings to form the through-hole vias with aligned recess areas in the metal layers.

The operation 703 may be directed to providing an etch inhibitor over a first section of each recess area in the metal layers.

The operation 704 may be directed to discharging a chemical etchant on the metal layers to selectively remove the metal layers from areas that are unobstructed by the etch inhibitor.

The operation 705 may be directed to providing an additional etch inhibitor over a second section of each recess area in the metal layers.

The operation 706 may be directed to discharging an additional chemical etchant on the metal layers to selectively remove the metal layers from areas that are unobstructed by the additional etch inhibitor.

The operations 703 through 706 may be repeated as needed to completely remove the metal layers.

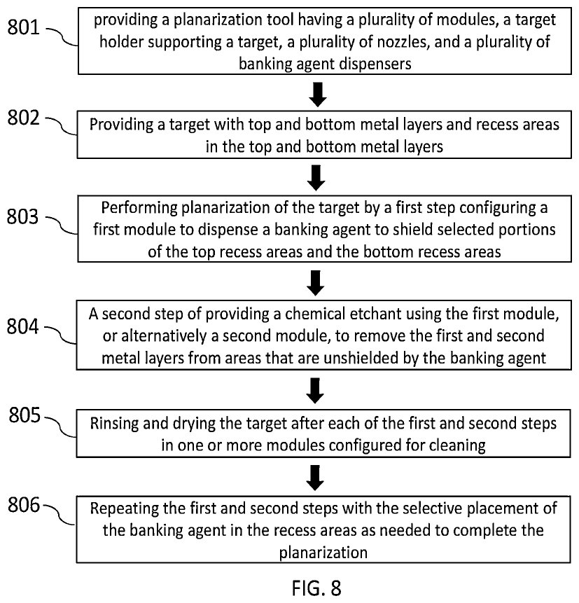

FIG. 8 shows a simplified flow diagram for another exemplary method according to an aspect of the present disclosure.

The operation 801 may be directed to providing a planarization tool having a plurality of modules, a target holder supporting a target, a plurality of nozzles, and a plurality of etch inhibitor dispensers.

The operation 802 may be directed to providing a target with top and bottom metal layers and recess areas in the top and bottom metal layers.

The operation 803 may be directed to performing planarization of the target by a first step of configuring a first module to dispense an etch inhibitor to shield selected sections of the top recess areas and the bottom recess areas.

The operation 804 may be directed to a second step of providing a chemical etchant using the first module, or alternatively a second module, to selectively remove the first and second metal layers from areas that are unshielded by the etch inhibitor.

The operation 805 may be directed to rinsing and drying the target after each of the first and second steps in one or more modules configured for cleaning to enable additional processing operations.

The operation 806 may be directed to repeating the first and second steps with the selective placement of the etch inhibitor in the recess areas as needed to complete the planarization process.

It will be understood that any property described herein for a specific module of the present planarization tool may also hold for any other modules described herein. It will also be understood that any property described herein for a specific method may hold for any of the methods described herein. Furthermore, it will be understood that for the present planarization tool and modules described herein, not necessarily all the components or operations described will be shown in the accompanying drawings or method, but only some (not all) components or operations may be disclosed.

To more readily understand and put into practical effect the present planarization tool and methods, they will now be described by way of examples. For the sake of brevity, duplicate descriptions of features and properties may be omitted.

### EXAMPLES

Example 1 provides a planarization tool including at least one module, the module including a target holder for support a target with a metal layer, and at least one of a plurality of etch inhibitor dispensers and/or a plurality of nozzles, for which the plurality of etch inhibitor dispensers discharge an etch inhibitor toward the target, and the plurality of nozzles discharge a chemical etchant at an acute angle towards the target to perform selective removal of the metal layer for planarization of the target.

Example 2 may include the planarization tool of example 1 and/or any other example disclosed herein, for which the plurality of nozzles and the plurality of etch inhibitor dispensers are provided in the planarization tool as a plurality of single discharge units that discharge the chemical etchant and the etch inhibitor together.

Example 3 may include the planarization tool of example 2 and/or any other example disclosed herein, for which the plurality of single discharge units includes a first set of single discharge units positioned over the target that discharges the chemical etchant and the etch inhibitor together at a downward discharge angle toward the target, and a second set of single discharge units positioned below the target that discharges the chemical etchant and the etch inhibitor together at an upward discharge angle towards the target.

Example 4 may include the planarization tool of example 1 and/or any other example disclosed herein, for which the at least one module includes a first module containing the plurality of etch inhibitor dispensers and a second module containing the plurality of nozzles.

Example 5 may include the planarization tool of example 3 and/or any other example disclosed herein, for which the plurality of nozzles further includes a rotation mechanism for adjusting the downward and upward discharge angles towards the target.

Example 6 may include the planarization tool of example 4 and/or any other example disclosed herein, which further includes a blower module for removing excess etch inhibitor from the target provided in the first module.

Example 7 may include the planarization tool of example 4 and/or any other example disclosed herein, which further includes a rinsing module for cleaning the target and a drying module for removing moisture from the target to permit additional processing operations.

Example 8 may include the planarization tool of example 4 and/or any other example disclosed herein, for which the target holder further includes a target handling system for conveying the target between modules for processing operations.

Example 9 may include the planarization tool of example 8 and/or any other example disclosed herein, which further includes a filtering system for removing the etch inhibitor that is used during operations of the planarization tool.

Example 10 provides a method that includes providing a target with first and second surfaces and openings extending from the first surface to the second surface for through-hole vias, depositing metal on the first surface and the second surface of the target, and filling the openings to form the through-hole vias, for which a first metal layer is formed with first recess areas aligned with each through-hole via on the first surface and a second metal layer is formed with second recess areas formed aligned with each through-hole via on the second surface, providing an etch inhibitor over a first section of each first recess area in the first metal layer, and discharging a chemical etchant onto the first metal layer, for which the chemical etchant selectively removes the first metal layer from areas that are unobstructed by the etch inhibitor.

Example 11 may include the method of example 10 and/or any other example disclosed herein, which further includes providing the etch inhibitor over a first section of each second recess area in the second metal layer, and discharging the chemical etchant on the second metal layer, for which the chemical etchant selectively removes the second metal layer from areas that are unobstructed by the etch inhibitor.

Example 12 may include the method of example 10 and/or any other example disclosed herein, which further includes providing an additional etch inhibitor over a second section of each first recess area and discharging an additional chemical etchant on the first metal layer, for which the additional chemical etchant selectively removes the first metal layer from areas that are unobstructed by the additional etch inhibitor.

Example 13 may include the method of example 11 and/or any other example disclosed herein, which further includes providing an additional etch inhibitor over a second section of each second recess area and discharging an additional chemical etchant on the second metal layer, for which the additional chemical etchant selectively removes the second metal layer from areas that are unobstructed by the additional etch inhibitor.

Example 14 may include the method of example 13 and/or any other example disclosed herein, which further includes inverting the target to configure the second surface as a top side before providing the etch inhibitor and discharging the chemical etchant, and providing the additional etch inhibitor and discharging the additional chemical etchant to the second metal layer.

Example 15 may include the method of example 12 and/or any other example disclosed herein, which further includes discharging the chemical etchant at a first discharge angle and discharging the additional chemical etchant at a second discharge angle.

Example 16 may include the method of example 10 and/or any other example disclosed herein, which further includes performing a cleaning process to remove the etch inhibitor and chemical etchant from the target to permit additional processing operations.

Example 17 provides a method that includes providing a planarization tool comprising at least one module, a target holder supporting a target, a plurality of nozzles, and a plurality of etch inhibitor dispensers, for which the target includes top and bottom surfaces and a plurality of openings extending from the top surface to the bottom surface for a plurality of through-hole vias, and the top surface is covered by a top metal layer with a top recess area formed in the top metal layer and the bottom surface is covered by a bottom metal layer with a bottom recess area formed in the bottom metal layer at each through-hole via, and planarizing the target by providing an etch inhibitor positioned over a first section of each of the top and bottom recess areas, respectively, in the top and bottom metal layers on the target, and discharging a chemical etchant at a first angle towards the target to at least partially remove the top and bottom metal layers from areas that are unobstructed by the etch inhibitor, and cleaning the target to remove the etch inhibitor and the chemical etchant.

Example 18 may include the method of example 17 and/or any other example disclosed herein, which further includes providing an additional etch inhibitor over a second section of each of the top and bottom recess areas, and discharging an additional chemical etchant at a second angle toward the target to selectively remove the top and bottom metal layers from areas that are unobstructed by the additional etch inhibitor, and cleaning the target to remove the additional etch inhibitor and the additional chemical etchant.

Example 19 may include the method of example 18 and/or any other example disclosed herein, for which the at least one module of the planarization tool includes a plurality of modules, and the method further includes conveying the target for operations at each of the plurality of modules, for which the plurality of modules are configured for operations to provide the etch inhibitor, discharge the chemical etchant, clean the etch inhibitor and the chemical etchant from the target, provide the additional etch inhibitor and discharge the additional chemical etchant.

Example 20 may include the method of example 17 and/or any other example disclosed herein, for which the plurality of nozzles and the plurality of etch inhibitor dispensers are configured in a single module of the planarization tool and the chemical etchant and the etch inhibitor are discharged together to selectively remove the top and bottom metal layers.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A planarization tool comprising:
at least one module, the module comprising:
a target holder, wherein a target with a metal layer is supported by the target holder; and
at least one of a plurality of etch inhibitor dispensers and/or a plurality of nozzles, wherein the plurality of etch inhibitor dispensers discharge an etch inhibitor toward the target and the plurality of nozzles discharge a chemical etchant at an acute angle towards the target to perform selective removal of the metal layer for planarization of the target.

2. The planarization tool of claim 1, wherein the plurality of nozzles and the plurality of etch inhibitor dispensers are provided in the planarization tool as a plurality of single discharge units that discharge the chemical etchant and the etch inhibitor together.

3. The planarization tool of claim 2, wherein the plurality of single discharge units comprises:
a first set of single discharge units positioned over the target that discharges the chemical etchant and the etch inhibitor together at a downward discharge angle toward the target; and
a second set of single discharge units positioned below the target that discharges the chemical etchant and the etch inhibitor together at an upward discharge angle towards the target.

4. The planarization tool of claim 1, wherein the at least one module comprises a first module containing the plurality of etch inhibitor dispensers and a second module containing the plurality of nozzles.

5. The planarization tool of claim 3, wherein the plurality of nozzles further comprises a rotation mechanism for adjusting the downward and upward discharge angles towards the target.

6. The planarization tool of claim 4, further comprises a blower module for removing excess etch inhibitor from the target provided in the first module.

7. The planarization tool of claim 4, further comprises a rinsing module for cleaning the target and a drying module for removing moisture from the target to permit additional processing operations.

8. The planarization tool of claim 4, wherein the target holder further comprises a target handling system for conveying the target between modules for processing operations.

9. The planarization tool of claim 1, further comprises a filtering system for removing the etch inhibitor that is used during operations of the planarization tool.

10. A method comprising:
providing a target with first and second surfaces and openings extending from the first surface to the second surface for through-hole vias;
depositing metal on the first surface and the second surface of the target and filling the openings to form the through-hole vias, wherein a first metal layer is formed with first recess areas aligned with each through-hole via on the first surface and a second metal layer is formed with second recess areas formed aligned with each through-hole via on the second surface;
providing an etch inhibitor over a first section of each first recess area in the first metal layer;
discharging a chemical etchant onto the first metal layer, wherein the chemical etchant selectively removes the first metal layer from areas that are unobstructed by the etch inhibitor.

11. The method of claim 10, further comprises:
providing the etch inhibitor over a first section of each second recess area in the second metal layer; and
discharging the chemical etchant on the second metal layer, wherein the chemical etchant selectively removes the second metal layer from areas that are unobstructed by the etch inhibitor.

12. The method of claim 10, further comprises:
providing an additional etch inhibitor over a second section of each first recess area; and
discharging an additional chemical etchant on the first metal layer, wherein the additional chemical etchant selectively removes the first metal layer from areas that are unobstructed by the additional etch inhibitor.

13. The method of claim 11, further comprises:
providing an additional etch inhibitor over a second section of each second recess area; and
discharging an additional chemical etchant on the second metal layer, wherein the additional chemical etchant selectively removes the second metal layer from areas that are unobstructed by the additional etch inhibitor.

14. The method of claim 13, further comprises inverting the target to configure the second surface as a top side before providing the etch inhibitor and discharging the chemical etchant, and providing the additional etch inhibitor and discharging the additional chemical etchant to the second metal layer.

15. The method of claim 12, further comprises discharging the chemical etchant at a first discharge angle and discharging the additional chemical etchant at a second discharge angle.

16. The method of claim 10, further comprises performing a cleaning process to remove the etch inhibitor and chemical etchant from the target to permit additional processing operations.

17. A method comprising:
providing a planarization tool comprising at least one module, a target holder supporting a target, a plurality of nozzles, and a plurality of etch inhibitor dispensers, wherein the target comprises top and bottom surfaces and a plurality of openings extending from the top surface to the bottom surface for a plurality of through-hole vias, and the top surface is covered by a top metal layer with a top recess area formed in the top metal layer and the bottom surface is covered by a bottom metal layer with a bottom recess area formed in the bottom metal layer at each through-hole via; and
planarizing the target by providing an etch inhibitor positioned over a first section of each of the top and bottom recess areas, respectively, in the top and bottom metal layers on the target, and discharging a chemical etchant at a first angle towards the target to at least partially remove the top and bottom metal layers from areas that are unobstructed by the etch inhibitor, and cleaning the target to remove the etch inhibitor and the chemical etchant.

18. The method of claim 17, further comprises:
providing an additional etch inhibitor over a second section of each of the top and bottom recess areas, and discharging an additional chemical etchant at a second angle toward the target to selectively remove the top and bottom metal layers from areas that are unobstructed by the additional etch inhibitor, and cleaning the target to remove the additional etch inhibitor and the additional chemical etchant.

19. The method of claim 18, wherein the at least one module of the planarization tool comprises a plurality of modules, and the method further comprises conveying the target for operations at each of the plurality of modules, wherein the plurality of modules are configured for operations to provide the etch inhibitor, discharge the chemical etchant, clean the etch inhibitor and the chemical etchant from the target, provide the additional etch inhibitor and discharge the additional chemical etchant.

20. The method of claim 17, wherein the plurality of nozzles and the plurality of etch inhibitor dispensers are configured in a single module of the planarization tool, and the chemical etchant and the etch inhibitor are discharged together to selectively remove the top and bottom metal layers.
